(19) United States
(12) Patent Application Publication
(10) Pub. No.: US 2023/0110410 A1
(43) Pub. Date: Apr. 13, 2023

(54) METHOD FOR MANUFACTURING COMPONENTS ON BOTH FACES OF A SUBSTRATE

(71) Applicant: COMMISSARIAT A L'ENERGIE ATOMIQUE ET AUX ENERGIES ALTERNATIVES, Paris (FR)

(72) Inventors: Pierre MONTMEAT, Grenoble Cedex 09 (FR); Franck FOURNEL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/958,801

(22) Filed: Oct. 3, 2022

(30) Foreign Application Priority Data
Oct. 8, 2021 (FR) 21 10687

(51) Int. Cl. H01L 21/683; H01L 21/67; C09J 7/35; C09J 7/50; C09J 183/08

(52) U.S. Cl. CPC H01L 21/6835; H01L 21/67103; C09J 7/35; C09J 7/50; C09J 183/08; H01L 2221/68372; C09J 2203/326; C09J 2301/304

(57) ABSTRACT

Method comprising the following steps:
i) manufacturing components on a face of a substrate fastened to a first temporary substrate,
ii) fastening a second temporary substrate onto the substrate,
iii) removing the first temporary substrate,
iv) manufacturing components on another face of the substrate,
the first and second temporary substrates having surface areas greater than the surface area of the substrate of interest,
during step ii), an adhesive film is disposed between the substrate and the first temporary substrate or between the substrate and the second temporary substrate,
the adhesive film forming a lateral band around the substrate and adhering to the temporary substrates,
the adhesion energy E₁ between the substrate of interest and the first temporary substrate being greater than the adhesion energy E₂ between the substrate of interest and the second temporary substrate,
the adhesion energy E₃₁ between the first temporary substrate and the adhesive film being lower than the adhesion energy E₃₂ between the second temporary substrate and the adhesive film.

### TECHNICAL FIELD

The present invention relates to the general field of film transfers.

The invention relates to a method for transferring films.

The invention also relates to a structure formed by several substrates.

The invention is of particular interest since it allows to create components on both faces of the same substrate, for example, a wafer made of silicon.

The invention has uses in numerous industrial fields, and in particular for the manufacturing of imagers, microphones or microelectromechanical systems (or MEMS).

### PRIOR ART

At present, to create components on both faces of a wafer made of silicon, temporary bonding techniques are implemented. For example, as shown in FIGS. 1A to 1E, the method for transferring film can comprise the following steps:
bonding a first temporary substrate of silicon 2 onto the front face 1a of a wafer made of silicon 1 (FIG. 1A),
optionally thinning the first substrate,
manufacturing components on the rear face 1b of the wafer 1,
bonding a second temporary substrate 3 onto the rear face 1b of the wafer 1 (FIG. 1B),
removing the first temporary substrate 2 (FIGS. 1C and 1D),
optionally thinning the first substrate,
manufacturing components on the front face 1a of the wafer made of silicon 1,
removing the second temporary substrate 3 (FIG. 1E).

It is the adhesion between, on the one hand, the wafer 1 and the first temporary substrate 2 and, on the other hand, between the wafer 1 and the second temporary substrate 3 that conditions the success of the transfer (or turning over).

Thus, this method is only possible if the adhesion E1 between the wafer 1 and the first temporary substrate 2 is lower than the adhesion E2 between the wafer 1 and the second temporary substrate 3. However, this is not always the case, sometimes E₁>E₂, and such a transfer method cannot therefore be implemented.

### Disclosure of the Invention

One goal of the present invention is to propose a method overcoming the disadvantages of the prior art and allowing to manufacture components on both faces of a substrate of interest by transfer of film even if the adhesion energy between the substrate of interest and the temporary substrate bonded at the front face is greater than the adhesion energy between the substrate of interest and the temporary substrate bonded at the rear face.

For this, the present invention proposes a method for manufacturing components on the two main faces of a substrate of interest comprising the following steps:

a) providing a substrate of interest having a first main face called front face and a second main face called rear face,

b) fastening a first temporary substrate onto the first main face of the substrate of interest, and optionally thinning the substrate of interest,

c) manufacturing components on the second main face of the substrate of interest,

d) positioning a second temporary substrate on the second main face of the substrate of interest,

e) rigidly connecting the second temporary substrate to the substrate of interest, preferably by implementing a heat treatment, to form a stack comprising the second temporary substrate/substrate of interest/first temporary substrate,

f) removing the first temporary substrate, and optionally thinning the substrate of interest,

g) manufacturing components on the first main face of the substrate of interest,

h) optionally, removing the second temporary substrate,

during step d), the first temporary substrate and the second temporary substrate each having a surface area greater than the surface area of the substrate of interest,

and an adhesive film being disposed between the first temporary substrate and the substrate of interest during step b) or between the substrate of interest and the second temporary substrate during step d),

by means of which during step e), the adhesive film forms a lateral band around the substrate of interest and adheres both to the first temporary substrate and to the second temporary substrate,

the adhesion energy E₁ between the substrate of interest and the first temporary substrate being greater than the adhesion energy E₂ between the substrate of interest and the second temporary substrate,

the adhesion energy E₃₁ between the first temporary substrate and the adhesive film being lower than the adhesion energy E₃₂ between the second temporary substrate and the adhesive film.

The invention fundamentally differs from the prior art by:
the positioning of an adhesive film between the first temporary substrate and the substrate of interest or between the substrate of interest and the second temporary substrate,
the use of a substrate of interest having a surface area smaller than that of the temporary substrates, which allows to form a lateral band of adhesive around the substrate of interest, during step e) for example by carrying out a heat treatment.

Thus, an adhesion between the two temporary substrates is obtained via the adhesive lateral band at the periphery of the temporary substrates. The adhesive lateral band is around the substrate of interest since the latter has a surface area smaller than that of the two temporary substrates. An adhesion E₃ between the two temporary substrates is thus obtained. E₃ is composed of two adhesions E₃₁ and E₃₂ respectively between the first temporary substrate and the adhesive band and between the second temporary substrate and the adhesive band, with E₃₁ smaller than E₃₂.

During step f), it is thus possible to separate the first temporary substrate from the stack formed by the first temporary substrate/substrate of interest/second temporary substrate, which would not be possible without the presence of the adhesive film. Indeed, since E₃₁<E₃₂ the separation is initiated at the interface with the first temporary substrate and then continues along this interface until the first temporary substrate is completely debonded. Without this bonding between the two temporary substrates at the periphery of the substrate of interest, since E₁ is greater than E₂, the initiation of the debonding would not be along the surface of the first temporary substrate but at the surface of the second temporary substrate, which would prevent the implementation of step f).

It is possible to initially have a substrate of interest having a smaller surface area than those of the temporary substrates or to reduce the dimensions of the substrate of interest during the method (for example after step b).

According to a first alternative embodiment, the adhesive film is disposed between the substrate of interest and the first temporary substrate, the adhesion energy E₁ between the substrate of interest and the first temporary substrate being greater than the adhesion energy E₂ between the substrate of interest and the second temporary substrate. The adhesion energy E₃₂ between the adhesive film and the second temporary substrate is greater than the adhesion energy E₃₁ between the adhesive film and the first temporary substrate.

According to this first alternative embodiment:
the substrate of interest and the second temporary substrate can be fastened to one another by direct bonding, or
a bonding layer, for example made of resin, can be disposed between the second temporary substrate and the substrate of interest during step d); preferably, the bonding layer does not extend beyond the surface of the substrate of interest.

According to a second alternative embodiment, the adhesive film is placed between the second temporary substrate and the substrate of interest.

Since the adhesion energy E₁ between the first temporary substrate and the substrate of interest is greater than the adhesion energy E₂ between the second substrate and the substrate of interest, without caution during a debonding it is indeed the second temporary substrate that is separated and not the first. According to the invention, via the creation of an adhesive joint between the two temporary substrates such that the adhesion energy E₃₁ between the adhesive film and the first substrate is lower than the adhesion energy E₃₂, during an unbonding in step f, it is the first temporary substrate that is separated from the substrate of interest/second temporary substrate structure.

According to this second alternative embodiment, the first substrate of interest and the temporary substrate can be fastened to one another by direct bonding or by a bonding layer for example made of resin. Preferably, the bonding layer does not extend beyond the surface of the substrate of interest.

Advantageously, the substrate of interest is made of a first material, the first temporary substrate is made of a second material and the second temporary substrate is made of a third material, the first material, the second material and the third material being independently chosen from silicon, silica, glass, sapphire, the ceramics for example SiC, germanium, a III-V material, for example AsGa, GaN or InP, a piezoelectric material, such as LNO or LTO, and a metal, preferably, molybdenum, tungsten, titanium, platinum or copper or an alloy.

Advantageously, the substrate of interest has a surface, the largest dimension of which is at least 200 μm, preferably at least 1 cm, smaller than the largest dimension of the surface of the first temporary substrate and/or than the largest dimension of the surface of the second temporary substrate.

Typically, the substrates are wafers (i.e. circular plates) and the largest dimension corresponds to the diameter. The lateral band thus has the shape of a ring.

Advantageously, the adhesive film is made from a thermoplastic material.

Advantageously, during step e) the adhesive film is heated to a temperature greater than the glass transition temperature of the adhesive film, with the applying of a pressure, by means of which the adhesive film becomes viscous and flows on either side of the substrate of interest until it contacts both the first temporary substrate and the second temporary substrate, thus forming an adhesive lateral band around the substrate of interest. It is possible to have a greater thickness of polymer at the bonding edge to facilitate this step.

Advantageously, a layer for managing adhesion is positioned between the adhesive film and the first temporary substrate during step b) or between the adhesive film and the second temporary substrate during step d).

For example, when the layer for managing adhesion is positioned between the adhesive film and the first temporary substrate, step b) can be carried out according to the following substeps:
depositing the adhesive film on the first main face of the substrate of interest,
depositing a layer for managing adhesion on the first temporary substrate,
placing the adhesive film and the layer for managing adhesion in contact,
optionally, carrying out a heat treatment to improve the adhesion between the layer for managing adhesion and the adhesive film.

Advantageously, the layer for managing adhesion is made of a fluorinated polymer, such as a fluoroacrylate, or made of an organosilicon compound such as octadecyltrichlorosilane or perfluorodecyltrichlorosilane.

The method is simple to implement and can be implemented for numerous materials.

The invention also relates to a structure obtained during the method described above, the structure successively comprising:
a first temporary substrate,
a substrate of interest, having a first main face and a second main face, the first main face facing the first temporary substrate, the second main face being covered by components,
a second temporary substrate,

the first temporary substrate and the second temporary substrate each having a surface area greater than the surface area of the substrate of interest,

an adhesive film being disposed between the first temporary substrate and the substrate of interest or between the substrate of interest and the second temporary substrate, the adhesive film forming a lateral band around the substrate of interest and adhering both to the first temporary substrate and to the second temporary substrate,

the adhesion energy E₁ between the first temporary substrate and the substrate of interest being greater than the adhesion energy E₂ between the second temporary substrate and the substrate of interest,

the adhesion energy E₃₁ between the first temporary substrate and the adhesive film being lower than the adhesion energy E₃₂ between the second temporary substrate and the adhesive film.

Other features and advantages of the invention will emerge from the following supplemental description.

It goes without saying that this supplemental description is only given as an illustration of the object of the invention and must in no case be interpreted as a limitation of this object.

### BRIEF DESCRIPTION OF THE DRAWINGS

The present invention will be better understood upon reading the description of exemplary embodiments given for purely informational and in no way limiting purposes while referring to the appended drawings in which:

FIGS. 1A to 1E, described above, show, schematically, various steps of a method according to the prior art.

FIGS. 2A to 2F show, schematically, various steps of a method according to a specific embodiment of the invention.

FIGS. 3A to 3F show, schematically, various steps of a method according to another specific embodiment of the invention.

FIGS. 4A to 4F show, schematically, various steps of a method according to another specific embodiment of the invention.

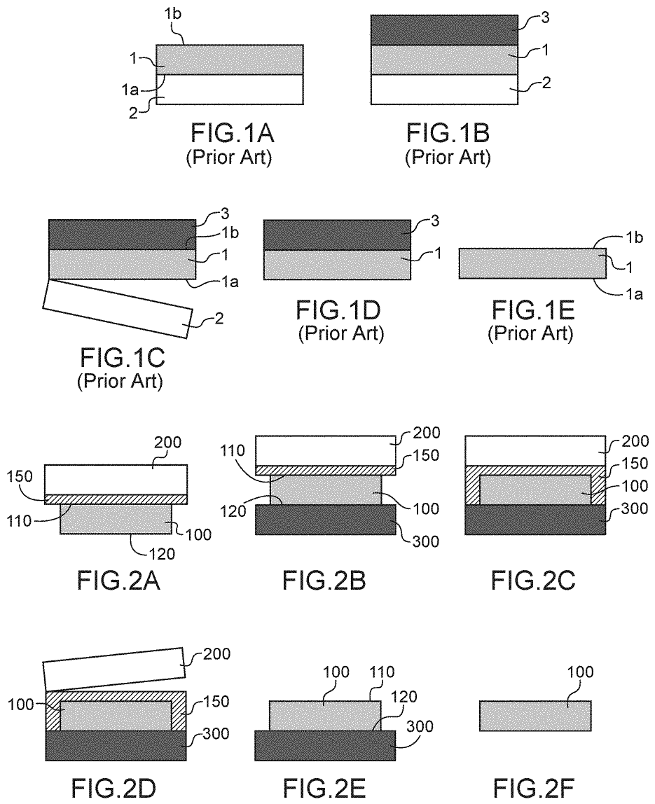

The various parts shown in the drawings are not necessarily according to a uniform scale, to make the drawings more readable.

Moreover, in the following description, terms that depend on the orientation, such as “on”, “under”, etc., of a structure apply while considering that the structure is oriented in the manner illustrated in the drawings.

### DETAILED DISCLOSURE OF SPECIFIC EMBODIMENTS

Although this is in no way limiting, the invention particularly has uses in the field of microelectronics, and in particular, to manufacture substrates made of silicon, the two main faces of which are covered by microelectronic components. In particular, the invention is of interest for the manufacturing of transistors, imagers, microelectromechanical systems (or MEMS) or microphones.

The invention can be transposed to other substrates, in particular to substrates made of silica, glass, sapphire, ceramic (for example SiC), germanium, III-V material such as AsGa, GaN or InP, piezoelectric material such as LNO/LTO or made of metal (for example molybdenum, tungsten, titanium, platinum or copper) or made of alloy.

The method for manufacturing components on the two main faces 110, 120 of a substrate of interest 100 can be carried out according to several embodiments for example shown in FIGS. 2A to 2F, 3A to 3F, 4A to 4F.

The various alternative embodiments of the method comprise at least the following steps:

a) providing a substrate of interest 100 having a first main face 110 called front face and a second main face 120 called rear face,

b) fastening a first temporary substrate 200 onto the first main face 110 of the substrate 100 (FIG. 2A, 3A, 4A), and optionally thinning the substrate of interest from its second main face,
if the first temporary substrate 200 has a surface area less than or equal to the surface area of the substrate of interest 100, reducing the surface area of the substrate of interest 100 until the surface area of the first temporary substrate 200 is greater than that of the substrate of interest 100,

c) manufacturing components on the second main face 120 of the substrate 100,

d) positioning a second substrate 300 on the second main face 120 of the substrate of interest 100 (FIG. 2B, 3B, 4B), the second temporary substrate 300 having a surface area greater than that of the substrate of interest 100,

e) rigidly connecting the second substrate 300 to the substrate of interest 100 (FIG. 2C, 3C, 4C), preferably by implementing a heat treatment,

f) removing the first temporary substrate 200 (FIGS. 2D-2E, 3D-3E, 4D-4E), and optionally thinning the substrate of interest from its first main face,

g) manufacturing components on the first main face 110 of the substrate of interest 100, by means of which a substrate of interest 100, the first main face 110 and the second main face 120 of which are covered by components is obtained,

h) optionally removing the second temporary substrate 300 (FIG. 2F, 3F, 4F).

According to these various specific embodiments, the substrate of interest 100 provided in step a) comprises a first main face 110 (front face) having a first surface and a second main face 120 (rear face) having a second surface, parallel or substantially parallel to each other. A lateral face having a thickness e goes from the first main face 110 to the second main face 120 of the substrate of interest 100. The first surface of the first main face 110 and the second surface of the second main face 120 have the same surface called surface of the substrate of interest.

The first temporary substrate 200 comprises a first main face and a second main face. The first main face of the first temporary substrate is fastened to the first main face 110 of the substrate of interest 100.

The second temporary substrate 300 comprises a first main face and a second main face. The first main face of the second temporary substrate 300 is fastened to the second main face 120 of the substrate of interest 100.

The substrate of interest 100, the first temporary substrate 200 and the second temporary substrate 300 are for example circular plates.

The substrate of interest 100 is made of a first material, the first temporary substrate 200 is a second material and the second temporary substrate 300 is made of a third material.

The first material, the second material and the third material can be identical or different.

The first material, the second material and the third material can be identical or different. The first material, the second material and the third material are independently chosen from the semiconductor materials, for example silicon or germanium, silica, glass, sapphire, the ceramics for example SiC, the III-V material such as AsGa, GaN or InP, the piezoelectric materials such as LNO/LTO or the metals (for example molybdenum, tungsten, titanium, platinum or copper) or the alloys.

For example, the first material, the second material and the third material can be silicon.

According to the invention, the substrate of interest 100 has a surface area smaller than the surface area of the first temporary substrate 200 and than the surface area of the second temporary substrate 300.

Preferably, the first temporary substrate 200 and the second temporary substrate 300 have the same surface area.

During step b) and/or during step f), it is possible to thin the substrate of interest 100 and/or to trim it in order to reduce the surface area of the main faces of the substrate of interest 100.

The width of the trimming of the substrate of interest 100 is, advantageously, greater than or equal to 200 μm, so as to ensure a sufficient surface of contact between the adhesive film 150 and the second temporary substrate 300. The trimming depends on the size of the substrate of interest 100. For a circular substrate 300 mm in diameter, a trimming of 1 cm can for example be chosen. For a smaller substrate of 50 mm, a trimming of between 100 μm and 1 mm is suitable.

According to the invention, an adhesive film 150 is disposed between the first temporary substrate 200 and the substrate of interest 100 during step b) or between the substrate of interest 100 and the second temporary substrate 300 during step d).

The adhesive film preferably covers the entire surface of the first face of the first temporary substrate 200 or the entire surface of the first face of the second temporary substrate 300.

The adhesive film 150 is, advantageously, made from a thermoplastic material. The product Brewer 305 marketed by Brewer Science or TOK zero newton TWN12000 marketed by TOKYO OHKA KOGYO Co is for example chosen.

The thickness of the adhesive film 150 is, for example, between 1 μm and 200 μm and preferably between 20 μm and 100 μm. The thickness of the adhesive film depends on the volume defined by the lateral wall of the substrate of interest 100, the first temporary substrate 200 and the second temporary substrate 300.

Advantageously, step e) is carried out by implementing a heat treatment, by means of which the adhesive film 150 becomes viscous, flows on either side of the substrate of interest 100 and forms a lateral band around the substrate of interest 100 and adheres both to the first temporary substrate 200 and to the second temporary substrate 300. In this step, it is considered that the viscosity of the adhesive film must preferably be less than or equal to 10⁻⁴ Pa.s to obtain good creep.

The lateral band is continuous from the first temporary substrate 200 to the second temporary substrate 300. The lateral band is, preferably, in contact with the lateral wall (also called side) of the substrate of interest 100. Alternatively, the lateral band cannot be in contact with the lateral wall of the substrate of interest 100 (i.e. an empty space can be present between the lateral wall of the substrate of interest and the lateral band).

The adhesion energy E₃₁ between the first temporary substrate 200 and the adhesive film 150 is lower than the adhesion energy E₃₂ between the second temporary substrate 300 and the adhesive film 150. Thus, the first temporary substrate 200 can be separated from the substrate of interest 100/second substrate of interest stack during step f).

In the absence of the lateral band of the adhesive film 150, there would be direct bonding between, on the one hand, the first temporary substrate 200 and the substrate of interest 100 and, on the other hand, between the second temporary substrate 300 and the substrate of interest 100, with the adhesion energy substrate of interest 100/first temporary substrate 200 greater than or equal to the adhesion energy substrate of interest 100/second temporary substrate 300. With this configuration, it is not therefore possible to implement step e).

According to the invention, the presence of the lateral band of the adhesive film allows to have an adhesion energy E₃₁ lower than E₃₂, which allows step e).

During step e), advantageously, a sufficiently high force and temperature are applied to the assembly. For example a force greater than or equal to 20 kN in the case of a substrate 300 mm in diameter can be applied and a temperature greater than or equal to 200° C. implemented.

According to a specific embodiment, the adhesive film can be in contact with the substrate of interest 100 and with the first temporary substrate 200 (FIG. 2A). Step b) of the method can comprise the following substeps:
positioning an adhesive film 150 between the first main face 110 of the substrate of interest 100 and the first temporary substrate 200,
carry out a heat treatment.

Alternatively, the adhesive film 150 can be disposed between the substrate of interest 100 and the second temporary substrate 300.

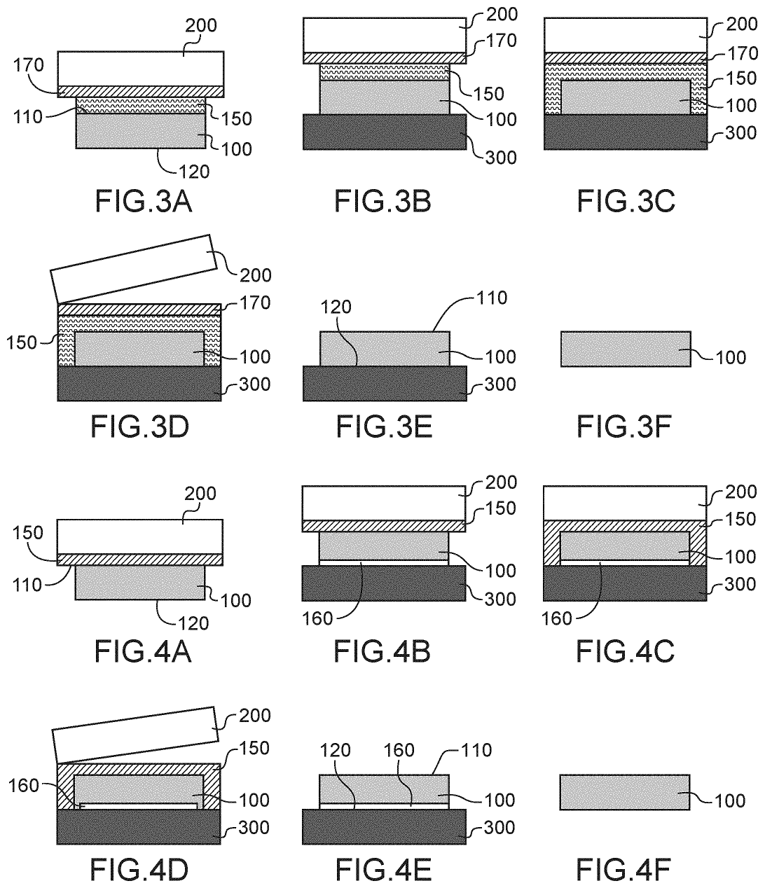

According to another specific embodiment, a layer for managing adhesion 170 can be disposed between the adhesive film 150 and the first temporary substrate 200 (FIG. 3A).

The overall adhesion energy between the first temporary substrate 200 and the adhesive film 150 can be decomposed into several energies of adhesion:
an adhesion energy between the first temporary substrate 200 and the layer for managing adhesion 170, and
an adhesion energy between the layer for managing adhesion 170 and the adhesive film 150.

The layer for managing adhesion 170 can be made of an organosilicon compound having at least one chlorine atom such as octadecyltrichlorosilane (OTS), perfluorodecyltrichlorosilane (FDTS), perfluorodecyldimethylchlorosilane (FDDMCS).

Organosilicon compound means a compound having at least one carbon-silicon bond.

The layer for managing adhesion 170 can be a fluorinated polymer, such as a fluoroacrylate or a polymer of the fluorosilane type. The fluorinated polymers marketed by the company 3M under the reference Novec 2702, Novec 1700 or Novec 1720 or the fluorinated polymers marketed by the company Daikin under the reference Optool are for example chosen.

The thickness of the layer for managing adhesion 170 is, for example, between 1 nm and 1 μm and preferably between 5 nm and 100 nm.

According to this specific embodiment, step b) of the method can comprise the following substeps:
depositing a layer for managing adhesion 170 on the first temporary substrate 200,
positioning an adhesive film 150 between the first main face 110 of the substrate of interest 100 and the first temporary substrate 200, and more particularly between the first main face 110 of the substrate of interest 100 and the layer for managing adhesion 170,
carrying out a heat treatment.

It is also possible to position the layer for managing adhesion 170 between the second main face 120 of the substrate of interest 100 and the second temporary substrate 300.

The layer for managing adhesion can partly or totally cover the first temporary substrate 200 or the second temporary substrate 300.

If the layer for managing adhesion partly covers the first temporary substrate 200 or the second temporary substrate 300, advantageously, it does not extend beyond the substrate of interest 100.

Preferably, the layer for managing adhesion 170 entirely covers the substrate 200.

According to another specific embodiment, on the one hand, the adhesive film is disposed during step b) between the substrate of interest 100 and the first temporary substrate 200 and, on the other hand, a bonding layer 160 is disposed between the second temporary substrate 300 and the substrate of interest (FIGS. 4A to 4E).

The bonding layer 160 does not totally cover the first main face of the second temporary substrate, thus the adhesive film 150 can contact the first main face of the second temporary substrate 300 during step e).

The bonding layer 160 is for example a resin. One of the resins marketed by JSR Corporation under the reference JSR HM8102 and JSR AR 1682J is for example chosen.

The thickness of the bonding layer 160 is, for example, between 1 nm and 100 μm and preferably between 10 nm and 10 μm.

According to this specific embodiment, step b) of the method can comprise the following substeps:
optionally, depositing a layer for managing adhesion 170 on the first temporary substrate 200 (not shown in the drawings),
positioning an adhesive film 150 between the first main face 110 of the substrate of interest 100 and the first temporary substrate 200 (FIG. 4A),
carrying out a heat treatment.

According to this third alternative embodiment, step d) can comprise the following substeps:
providing a second temporary substrate 300,
depositing a bonding layer 160 between the second temporary substrate 300 and the second main face 120 of the substrate of interest 100, wherein the bonding layer 160 can be deposited on the substrate of interest 100 and/or on a part of the main face of the second temporary substrate 300 (FIG. 4B).

For these various embodiments described above, during step f), the adhesive film 150 is removed. The adhesive film 150 can be removed by a cleaning via a suitable solvent. The solvent is for example chosen from the alcohols and the hydrocarbons, or one of their mixtures. For illustrative purposes, a first cleaning using D-limonene followed by a rinsing using isopropyl alcohol (also called propan-2-ol) can be chosen.

The adhesive lateral band can be removed during step f) or h).

The lateral band can be removed with the same solvent as that used to remove the adhesive film.

During steps c) and g), components are manufactured, respectively, on the second main face 120 of the substrate of interest 100 (rear face) and on the first main face 110 of the substrate of interest 100 (front face). The manufacturing of these components can include for example steps of lithography, ion etching, depositions, polishing, implantation. On the same main face of the substrate of interest, the components can be identical or different. The components of the first main face of the substrate of interest 100 can be identical or different than the components of the second main face of the substrate of interest 100.

During step h), the second temporary substrate 300 is separated from the substrate of interest 100. For this, the first main face 110 of the substrate of interest 100 can be fastened to a metal frame for example of the DISCO type with the use of an adhesive film in a conventional manner in temporary bonding.

By inserting a wedge into the stack, the second temporary substrate 300 can be separated from the substrate of interest 100. The substrate 100 can then undergo a cutting out step to separate the various components to be finally separated from the metal frame.

The temporary substrates 200, 300 can be reused, for example, to manufacture components on another substrate of interest.

### Illustrative and Non-Limiting Examples of Various Embodiments

In the following examples 1 to 3 and 5, the first temporary substrate 200 and the second temporary substrate 300 are silicon wafers 300 mm in diameter. The substrate of interest 100 is obtained by trimming a silicon wafer 300 mm in diameter.

For example 4, the first temporary substrate 200 and the second temporary substrate 300 are silicon wafers 200 mm in diameter. The substrate of interest 100 is obtained by trimming a silicon wafer 200 mm in diameter.

### Example 1

On the first temporary substrate 200, a fluorinated film of Novec 2702 is spread and the assembly is annealed at 150° C. for 30 min to form a layer for managing adhesion 170.

Via a diamond saw, a silicon wafer is trimmed over a width of 1.5 mm and a depth of 200 μm to form the substrate of interest 100. An adhesive film 150 is formed on this substrate of interest 100 by spreading 40 μm of Brewer 305 resin and this assembly is bonded at 210° C. with the first temporary substrate 200 so as to create an interface between the adhesive film 150 and the layer for managing adhesion 170.

The surface energy of the bonding is evaluated by the method described in the article by Maszara et al. (J. Appl. Phys. 64 (1988) 4943-4950). The adhesion energy between the first temporary substrate 200 and the substrate of interest 100 is 0.4 J/m². In all the examples, the energies of adhesion will be determined by this method.

The substrate of interest 100 is thinned to 20 μm by mechanical abrasion via a diamond wheel. Then, the surface of the substrate of interest 100 undergoes a wet cleaning and a polishing. On a second temporary substrate 300, JSR HM8102 resin is spread to have a bonding layer 160 50 nm thick. A direct bonding (defined as spontaneous bonding without an intermediate liquid layer) of the second temporary substrate 300 onto the substrate of interest 100/first temporary substrate 200 assembly via resin is carried out. The energy of direct adhesion between the resin and the second temporary substrate 300 is less than 0.2 J/m². This energy is not modified by an annealing carried out between 100 and 200° C. In particular, this adhesion is lower than the adhesion of the substrate of interest 100/first temporary substrate 200 stack. If this assembly is separated without caution, the second temporary substrate 300 is separated from the substrate of interest 100/first temporary substrate 200 assembly.

The structure thus obtained comprising the substrate of interest 100 and the two temporary substrates 200, 300 undergoes annealing at 200° C. under a force of 20 kN in such a way as to make the adhesive 150 flow and form a lateral band contacting the second temporary substrate 300. The adhesion of the interface between the lateral band of the adhesive film 150 and the second temporary substrate 300 is estimated at 2 J/m² and is much stronger than the adhesion between the first temporary substrate 200 and the substrate of interest 100. By inserting a wedge into this stack, the first temporary substrate 200 is separated from the assembly. A D-limonene then isopropyl alcohol cleaning allows to pickle the surface of the substrate of interest 100.

A technological step can thus be carried out on the substrate 100. For example a deposition of TEOS at 150° C. on the front face of the substrate of interest 100 can be carried out. Then the assembly is mounted on a DISCO metal frame via a Furukawa SP-537T-230 adhesive film. By inserting a wedge into the stack, the substrate of interest 100 is separated from the second temporary substrate 300.

### Example 2

On the first temporary substrate 200, a fluorinated film of Novec 1720 is spread and the assembly is annealed at 130° C. for 5 min to form a layer for managing adhesion 170.

Via a diamond saw, a silicon wafer is trimmed over a width of 0.5 mm and a depth of 200 μm to form the substrate of interest 100. 40μm of Brewer 305 adhesive is spread to form an adhesive film 150 on this substrate 100 and this assembly is bonded at 210° C. with the first temporary substrate 200 so as to create an interface between the adhesive film 150 and the layer for managing adhesion 170.

The adhesion energy of the bonding between the first temporary substrate 200 and the substrate of interest 100 is evaluated: 0.4 J/m².

The substrate of interest 100 is thinned to 20 μm by mechanical abrasion via a diamond wheel. The surface of the substrate of interest 100 undergoes a wet cleaning and a polishing. On the second temporary substrate 300, 270 nm of JSR AR1682J resin is spread to form a bonding layer 160. The resin is trimmed over a width of 1 mm. A bonding of the second temporary substrate 300 onto the first temporary substrate 200/substrate of interest 100 assembly is carried out via the resin. The trimming of 1 mm of the resin JSR AR1682J allows to ensure contact between the Brewer 305 adhesive and the second temporary substrate 300. The adhesion of the second temporary substrate 300/substrate of interest 100 interface remains below 0.2 J/m² regardless of the annealing carried out between 100 and 175° C. In particular, this adhesion is lower than the adhesion between the first temporary substrate 200 and the substrate of interest 100. If this assembly is separated without caution, the second temporary substrate 300 is separated from the assembly.

The structure thus obtained undergoes annealing at 175° C. under a force of 20 kN. The adhesion between the adhesive 150 and the second temporary substrate 300 is estimated at 2 J/m² and is much stronger than the substrate of interest 100/second temporary substrate 300 interface. By inserting a wedge into this stack, the first temporary substrate 200 is separated from the substrate of interest 100/second temporary substrate 300 assembly. A D-limonene then isopropyl alcohol cleaning allows to pickle the surface of the substrate of interest 100.

A deposition of SiH₄ is carried out at 150° C. on the front face 110 of the substrate of interest 100. Then the assembly is mounted on a DISCO metal frame via a Furukawa SP-537T-230 adhesive film. By inserting a wedge into the stack, the substrate of interest 100 is separated from the second temporary substrate 300.

### Example 3

On the first temporary substrate 200, a fluorinated film of Novec 1720 is spread and the assembly is annealed at 130° C. for 5 min to form a layer for managing adhesion 170.

Via a diamond saw, a substrate of interest silicon wafer is trimmed over a width of 0.5 mm and a depth of 200 μm to form the substrate of interest 100. 40 μm of Brewer 305 adhesive is spread on this wafer 100 thus forming an adhesive film 150 and this assembly is bonded at 210° C. onto the first temporary substrate 200 so as to create an interface between the adhesive film 150 and the layer for managing adhesion 170.

The adhesion energy of the bonding is evaluated: 0.4 J/m².

The substrate of interest 100 is thinned to 20 μm by mechanical abrasion via a diamond wheel. The surface of the substrate of interest 100 undergoes a wet cleaning and a polishing. After polishing of the surface of the substrate of interest 100, a treatment by an aqueous solution of HF (5%) is carried out so as to make this surface hydrophobic. The second temporary substrate 300 also undergoes a treatment by an aqueous solution of HF (5%) so as to make its surface hydrophobic. The second temporary substrate 300 is assembled onto the substrate of interest 100 by direct bonding. The adhesion of the interface between the substrate of interest 100 and the second temporary substrate 300 remains below 0.1 J/m² regardless of the annealing carried out between 100 and 250° C. In particular, this adhesion is lower than the adhesion of the substrate of interest 100/first temporary substrate 200 stack. If this assembly is separated without caution, the second temporary substrate 300 is separated from the substrate of interest 100/first temporary substrate 200 assembly.

The structure thus obtained undergoes annealing at 200° C. under a force of 20 kN. The adhesion between the adhesive 150 and the second temporary substrate 300 is estimated at 2 J/m² and is much stronger than the substrate of interest 100/second temporary substrate 300 interface. By inserting a wedge into this stack, the first temporary substrate 200 is separated from the substrate of interest 100/second temporary substrate 300 assembly. A D-limonene—isopropyl alcohol cleaning allows to pickle the surface of the substrate of interest 100.

An annealing of 2 hours at 800° C. of the substrate of interest 100/second temporary substrate 300 assembly reinforces the adhesion of the substrate of interest 100/second temporary substrate 300 bonding interface.

### Example 4

On the first temporary substrate 200, a film of ODTS (octadecyltrichlorosilane) in solution in isooctane is spread to form a layer for managing adhesion 170.

Via a diamond saw, a silicon wafer is trimmed over a width of 0.5 mm and a depth of 200 μm to form the substrate of interest 100. 40 μm of Brewer 305 adhesive is spread on this wafer to form an adhesive film 150. This assembly is bonded at 210° C. onto the first temporary substrate 200 so as to create an interface between the adhesive film 150 and the layer for managing adhesion 170.

The adhesion energy of the bonding is evaluated at 0.2 J/m².

The substrate of interest 100 is thinned to 20 μm by mechanical abrasion via a diamond wheel. The substrate of interest 100 surface undergoes a wet cleaning and a polishing. After polishing of the substrate of interest 100 surface, a treatment by an aqueous solution of ammonia and oxygenated water (NH₄OH 30%, H₂O₂ 30%, water in proportions of 1-1-5) at 70° C. for 10 mn followed by an aqueous solution of HF (5%) is carried out so as to make this surface slightly rough (2.3 nm RMS measured by AFM on a scan of 1*1 μm²) and hydrophobic. The second temporary substrate 300 also undergoes a treatment by an aqueous solution of HF (5%) so as to make its surface hydrophobic. A direct bonding of the second temporary substrate 300 onto the substrate of interest 100 is carried out. The adhesion of the substrate of interest 100/second temporary substrate 300 interface remains below 0.1 J/m² regardless of the annealing carried out between 100 and 250° C. In particular, this adhesion is lower than the adhesion of the substrate of interest 100/first temporary substrate 200 stack. If this assembly is separated without caution, the second temporary substrate 300 is separated from the substrate of interest 100/first temporary substrate 200 assembly.

The structure thus obtained undergoes annealing at 200° C. under a force of 20 kN. The adhesion between the adhesive 150 and the second temporary substrate 300 is estimated at 2 J/m² and is much stronger than the substrate of interest 100/second temporary substrate 300 interface. By inserting a wedge into this stack, the first temporary substrate 200 is separated from the substrate of interest 100/second temporary substrate 300 assembly. A D-limonene—isopropyl alcohol cleaning allows to pickle the surface of the second temporary substrate 300.

An annealing of 2 hours at 800° C. of the substrate of interest 100/second temporary substrate 300 assembly is carried out so as to reinforce the adhesion of the substrate of interest 100/second temporary substrate 300 bonding interface.

### Example 5

On the first temporary substrate 200, a film of perfluorodecyldimethylchlorosilane (FDDMCS) in solution in isooctane is spread to form a layer for managing adhesion 170.

Via a diamond saw, a silicon wafer is trimmed over a width of 0.5 mm and a depth of 200 μm to form the substrate of interest 100. A TOK zero newton TWM12000 film of 100 μm is spread on the substrate of interest 100 and this assembly is bonded at 180° C. onto the first temporary substrate 200.

The adhesion energy of the bonding is evaluated at 1 J/m².

The substrate of interest 100 is thinned to 40 μm by mechanical abrasion via a diamond wheel. The surface of the substrate of interest 100 undergoes a wet cleaning and a polishing. After polishing of the surface of the substrate of interest 100, a treatment by an aqueous solution of HF (5%) is carried out so as to make this surface hydrophobic. The second temporary substrate 300 also undergoes a treatment by an aqueous solution of HF (5%) so as to make its surface hydrophobic. The second temporary substrate 300 is assembled onto the substrate of interest 100 by direct bonding. The adhesion of the substrate of interest 100/second temporary substrate 300 interface remains below 0.5 J/m² regardless of the annealing carried out between 100 and 250° C. In particular, this adhesion is lower than the adhesion of the substrate of interest 100/first temporary substrate 200 stack. If this assembly is separated without caution, the second temporary substrate 300 is separated from the substrate of interest 100/first temporary substrate 200 assembly.

The first temporary substrate 200/substrate of interest 100/second temporary substrate 300 structure undergoes annealing at 240° C. under a force of 15 kN. The adhesion between the adhesive 150 and the second temporary substrate 300 is estimated at 2 J/m² and is much stronger than the substrate of interest 100/second temporary substrate 300 interface. By inserting a wedge into this stack, the first temporary substrate 200 is separated from the substrate of interest 100/second temporary substrate 300 assembly. A cleaning with acetone allows to pickle the surface of the substrate of interest 100.

1. Method for manufacturing components on the two main faces of a substrate of interest comprising the following steps:
a) providing a substrate of interest having a first main face and a second main face,
b) fastening a first temporary substrate onto the first main face of the substrate of interest,
c) manufacturing components on the second main face of the substrate of interest,
d) positioning a second temporary substrate on the second main face of the substrate of interest,
e) rigidly connecting the second temporary substrate to the substrate of interest,
f) removing the first temporary substrate,
g) manufacturing components on the first main face of the substrate of interest,
wherein during step d), the first temporary substrate and the second temporary substrate each have a surface area greater than the surface area of the substrate of interest,
and wherein an adhesive film is disposed between the first temporary substrate and the substrate of interest during step b) or between the substrate of interest and the second temporary substrate during step d),
by means of which during step e), the adhesive film forms a lateral band around the substrate of interest and adheres both to the first temporary substrate and to the second temporary substrate,
the adhesion energy E₁ between the substrate of interest and the first temporary substrate being greater than the adhesion energy E₂ between the substrate of interest and the second temporary substrate,
the adhesion energy E₃₁ between the first temporary substrate and the adhesive film being lower than the adhesion energy E₃₂ between the second temporary substrate and the adhesive film.

2. Method according to claim 1, wherein during step e) the adhesive film is heated to a temperature greater than the glass transition temperature of the adhesive film, by means of which the adhesive film becomes viscous and flows on either side of the substrate of interest until it contacts both the first temporary substrate and the second temporary substrate, thus forming an adhesive lateral band around the substrate of interest.

3. Method according to claim 1, wherein the adhesive film is disposed between the first temporary substrate and the substrate of interest and wherein the substrate of interest and the second temporary substrate are fastened to one another by direct bonding.

4. Method according to claim 1, wherein the adhesive film is disposed between the first temporary substrate and the substrate of interest and wherein a bonding layer is disposed between the second temporary substrate and the substrate of interest during step d).

5. Method according to claim 4, wherein the bonding layer is made of resin.

6. Method according to claim 1, wherein the adhesive film is disposed between the second temporary substrate and the substrate of interest and wherein the substrate of interest and the first temporary substrate are fastened to one another by direct bonding.

7. Method according to claim 1, wherein the adhesive film is made of a thermoplastic material.

8. Method according to claim 1, wherein the substrate of interest has a surface, the largest dimension of which is at least 200 μm smaller than the largest dimension of the surface of the first temporary substrate and than the largest dimension of the surface of the second temporary substrate.

9. Method according to claim 8, wherein the substrate of interest has a surface, the largest dimension of which is at least 1 cm smaller than the largest dimension of the surface of the first temporary substrate and than the largest dimension of the surface of the second temporary substrate.

10. Method according to claim 1, wherein the substrate of interest is made of a first material, the first temporary substrate is made of a second material and the second temporary substrate is made of a third material, the first material, the second material and the third material being independently chosen from silicon, silica, glass, sapphire, the ceramics, germanium, a III-V material, a piezoelectric material, a metal and an alloy.

11. Method according to claim 1, wherein a layer for managing adhesion is positioned between the adhesive film and the first temporary substrate during step b) or between the adhesive film and the second temporary substrate during step d).

12. Method according to claim 11, wherein the layer for managing adhesion is made of a fluorinated polymer or made of an organosilicon compound.

13. Method according to claim 12, wherein the layer for managing adhesion is made of a fluoroacrylate polymer.

14. Method according to claim 12, wherein the layer for managing adhesion is made of octadecyltrichlorosilane or perfluorodecyltrichlorosilane.

15. Method according to claim 1, wherein step e) of rigidly connecting the second temporary substrate to the substrate of interest is performed by implementing a heat treatment.

16. Method according to claim 1, wherein the method comprises, after step g), a step h) of removing the second temporary substrate.

17. Method according to claim 1, wherein, during step b), after fastening the first temporary substrate onto the first main face of the substrate of interest, a thinning of the substrate of interest is performed.

18. Method according to claim 1, wherein, during step f), after removing the first temporary substrate, a thinning the substrate of interest is performed.

19. Structure successively comprising:
a first temporary substrate,
a substrate of interest, having a first main face and a second main face, the first main face facing the first temporary substrate, the second main face being covered by components,
a second temporary substrate,
wherein the first temporary substrate and the second temporary substrate each have a surface area greater than the surface area of the substrate of interest,
and wherein an adhesive film is disposed between the first temporary substrate and the substrate of interest or between the substrate of interest and the second temporary substrate,
and wherein the adhesive film forms a lateral band around the substrate of interest and adheres both to the first temporary substrate and to the second temporary substrate,
the adhesion energy E₁ between the first temporary substrate and the substrate of interest being greater than the adhesion energy E₂ between the second temporary substrate and the substrate of interest,
the adhesion energy E₃₁ between the first temporary substrate and the adhesive film being lower than the adhesion energy E₃₂ between the second temporary substrate and the adhesive film.
